(19) United States
(12) Patent Application Publication
(10) Pub. No.: US 2004/0217366 A1
(43) Pub. Date: Nov. 4, 2004

(54) Fabrication of alignment and assembly microstructures

(76) Inventors: Michael Thomas Gale, Wettswil (CH); Thomas Ammer, Pfaffikon (CH)

Correspondence Address: FISH & RICHARDSON, PC, 12390 EL CAMINO REAL, SAN DIEGO, CA, 92130-2081, US

(21) Appl. No.: 10/475,506

(22) PCT Filed: Jul. 29, 2002
(86) PCT No.: PCT/GB02/03482

(30) Foreign Application Priority Data
Jul. 30, 2001 (GB) 0118511.5

(51) Int. Cl. H01L 33/00

(52) U.S. Cl. 257/98

(57) ABSTRACT

This invention relates to the assembly of optical microsystems by passive alignment techniques. A technique is described for the fabrication of optimised structural elements with rounded edges (continuous-relief) for providing means for integration with active or passive micro-optical elements, optical fibres or with other microsystem components. The use of replication technology for producing the microstructures on individual devices or on complete wafers allows production in high volume and at a low cost per piece. The shape of the microstructures offers similar functionality for alignment purposes as etched silicon V-grooves, but the fabrication process gives more degrees of freedom for the layout design. A particular feature is the possibility to fabricate circular alignment grooves for the vertical alignment of optical fibres to Vertical Cavity (VCSEL) laser structures.

The invention relates to the fabrication of continuous-relief, round-edged microlithographic alignment and assembly structures and is relevant for the integration and packaging of optoelectronic components and optical microsystems.

The fabrication of optical microsystems requires the precise alignment (often to sub-micrometer tolerances) of optical microsystem components such as fibres, microlenses and other micro-optical components to corresponding components or to optoelectronic devices such as lasers, VCSELs (Vertical Cavity Surface is Emitting Lasers), detectors and optical waveguides. This can be accomplished in various ways. These include the etching of grooves in glass substrates or silicon wafers for the placement of the components. The fabrication of such supporting substrates and the mounting of components on them requires time consuming and costly techniques. Current techniques involving structures such as V-grooves are also not optimal for aligning components oriented vertically to a wafer or device plane, for example fibre or a fibre array to devices on a wafer.

For cost-effective production technology, passive alignment techniques are preferred in which the components can be simply inserted into mechanical alignment structures produced during or subsequent to the basic microsystem or device fabrication process. The alternative, active alignment in which, for example, a device such as a laser is activated and the alignment carried out by optimising throughput in the components to be aligned, results in best precision, but is generally time consuming and not suitable for wafer scale processing.

The integration of passive alignment structures for vertical coupling of optical fibres and fibre arrays directly on top of VCSEL chips produces packaging and fibre coupling issues that are still time consuming and costly and the associated problems have not yet been fully and satisfactorily solved. VCSELs are well-established devices with major applications in Datacom, Telecom and other areas [1]. Conventional methods comprise, for example, the manual or automated active alignment of optical fibres with subsequent encapsulation (pig-tailing), the use of microprisms in combination with horizontally mounted fibre arrays or ribbons and the use of flexible waveguide structures as interconnecting part between lasers and fibre sockets [2].

It is an object of the invention to provide microstructures to be integrated at a wafer scale level or on partially processed devices with active or passive optoelectronic devices (e.g. VCSEL arrays, detector arrays) for the subsequent passive alignment of optical fibres, micro-optical elements or parts of an optical microsystem.

It is another object of the invention to provide microstructures to be integrated on parts of an optical microsystem for passive alignment of similar parts with respect to each other (e.g. a stack of micro-optical elements).

It is a further object of the invention to produce one or two-dimensional arrays of optical fibres on a transparent block or substrate, a semiconductor wafer, or part of an optical microsystem.

The invention provides a microstructure formed on or for application to a surface of a substrate in which one or more optoelectronic devices are formed, the microstructure having one or more apertures aligned with the optoelectronic devices and extending inwardly from an external surface thereof, the outer edges of the apertures being rounded in a plane normal to the external surface.

The invention further provides a method of fabricating such a microstructure comprising the steps of:

depositing a high viscosity positive photo resist film on a substrate;

drying the resist film on a thermal hotplate running a ramped temperature profile;

exposing the film by contact mask lithography;

developing the film using a positive photo resist developer; and

subjecting the substrate to an extended and optimised hard bake in a convection oven to produce a controlled rounding of the edges of the microstructure.

The invention still further provides a method of component insertion comprising the steps of:

producing a microstructure according to the invention; and

loading the component by inserting it into one or more of said apertures.

The invention yet further provides a method of assembling a component comprising the steps of:

locating a microstructure according to the invention on a substrate;

inserting the component into one or more of said apertures; and

fixing the component with respect to the microstructure.

Various preferred, advantageous or alternative features of the invention are set forth in dependent claims to which reference should now be made.

The fabrication technique according to the invention offers a cost effective way to integrate circular alignment microstructures on top of the VCSEL surface, either by direct processing of the device wafer or by transfer in a replication process. Optical fibres can then be passively inserted and subsequently encapsulated with the device.

The above and other features and advantages of the invention will be apparent from the following description, by way of example, of embodiments of the invention.

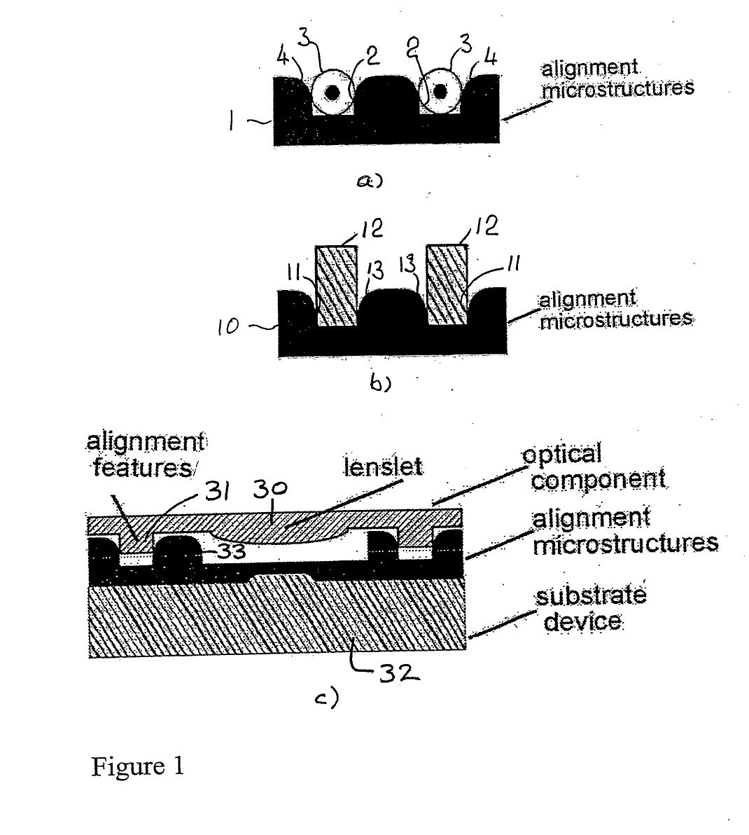

FIG. 1 shows microstructures according to the invention.

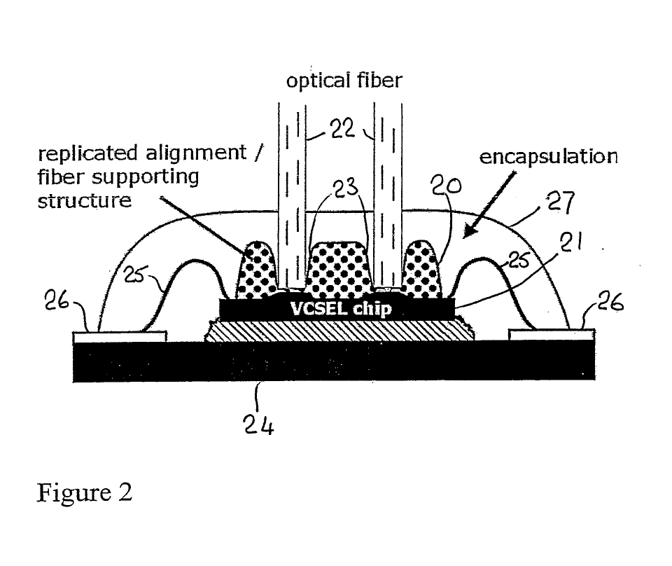

FIG. 2 shows a microstructure aligned with a VCSEL chip.

The present invention provides an approach and fabrication method which is suitable for the integration of passive alignment microstructures directly on the component. The object of the invention is to fabricate single or multiple (array) of optimised alignment microstructure features which enable an optimal, cost-effective assembly of the microsystem components. The microstructures can be fabricated at a wafer-scale level directly on top of a device wafer (e.g. VCSEL or detector chips), or on an individual device or component. A preferred approach is the transfer of the microstructure to the component surface by a replication process such as UV-casting or injection moulding.

The invention provides the fabrication of optimised, continuous-relief microstructures with rounded edges for the purpose of integration within optical Microsystems or on a wafer-scale level with VCSEL or optical detector chips. A major application of such microstructures is passive alignment and assembly of optical fibres with micro-optical or electro-optical (lasers, detectors) elements. Supporting or alignment structures can have arbitrary two-dimensional layout shapes. For example, one and two-dimensional arrays of alignment grooves for horizontal or vertical optical fibre alignment are feasible. The fabrication process is well suited for tool-origination for low-cost replication techniques such as injection moulding or UV-casting [3].

Embodiments of the invention consist of one or more of the following steps:

1. Fabrication of single or multiple (array) microstructures with continuous-relief profiles optimised for subsequent passive alignment of the desired optical microsystem components. The microstructure fabrication process is based on thick-film positive photoresist lithography with subsequent thermal reflow.

2. Fabrication of a replication mould.

3. Production of the alignment microstructures on individual devices or whole wafers using replication technology.

4. Insertion and assembly of the microsystem components.

The following gives more details of the individual steps:

The fabrication of microstructure with optimal rounded edges is critical for the subsequent insertion and alignment of components. The rounded edges allow insertion, for example of a fibre in a hole, with relatively low requirement on the component positioning. The alignment is passive (no electrically activated components) and high precision due to the taper in the microstructure.

The fabrication method employs the following steps:

a) A high viscosity positive photoresist film is deposited on a silicon wafer, an optoelectronic device wafer or a glass substrate by spin coating. The film thickness is determined by the rotation speed and time. The typical thickness range is between 10 and 100 micrometers.

b) The drying (soft-bake) of the resist film is carefully carried out on a microprocessor controlled thermal hotplate running a ramped temperature profile. The ramping parameters are specific to the used resist type and thickness.

c) The film is exposed by contact mask lithography in a standard mask aligner.

d) The exposed film is patterned by development using standard diluted positive photoresist developer.

e) The substrate is subjected to an extended and carefully optimised hard-bake in a convection oven for a thermal reflow of the resist matrix. This results in a controlled rounding of the edges of the microstructure and a taper in the insertion hole. The top of the microstructure is such that it allows insertion of the matching component with a relatively low initial positioning accuracy requirement. Further insertion into the microstructure then accurately aligns the component. Examples of types of microstructure which can be produced by this approach are shown in FIG. 1.

An example of a resist type and processing parameters for the above is as follows:

| | |
|---|---|
| Substrate | 4″ Borofloat glass wafer, 1 mm thick |
| Primer | HDMS (standard adhesion |
| | promoter treatment) 4000 rpm |
| Photoresist | Shipley SPR 220-7 (Product of |
| | Shipley Company, Marlborough, Massachusetts) |
| Coating thickness | 60 micrometers |
| Softbake (step b) | Hotplate with lid |
| Ramping: | 30 minutes-Room temperature to 115° C. |
| | 10 minutes-Hold at 115° C. |
| | 45 minutes-115° C. to Room temperature |
| Reflow (step e) | Optimised hardbake: |
| | 10 minutes at 100° C. placed on 1 mm |
| | thick glass substrate in convection oven |
| | Then place substrate on glass |
| | in oven to cool down |

A replication mould may be fabricated from the original structure. Standard techniques for electroplating a mould in Ni are described in Reference 3. A preferred approach for this invention is the fabrication of an elastomeric casting mould in a heteropolysiloxane material such as PDMS. This gives a precise but slightly elastic mould which is highly suited to the UV-replication of such microstructures.

Using the replication mould, the microstructure is replicated:

on an individual device, such as a mounted (and bonded) VCSEL as shown in FIG. 2.

onto a complete wafer with partially processed devices such as VCSELs or detector elements or

onto a microsystem component or sub-system.

Information on replication techniques can be found in Reference 3.

A preferred approach is to replicate into a uv-curable polymer such as NOA61 (product of Norland Company, US) or a sol-gel such as an ORMOCER material (Trademark of Fraunhofer Gesellschaft, Germany). The replication can be carried out using a high-precision robot to dispense the material and position the mould. For wafer scale replication, a modified mask aligner or other suitable equipment can be used.

An alternative is to use injection moulding technology, for example as described in U.S. Pat. No. 5,833,902: Injection Molding Encapsulation for an Electronic Device Directly onto a Substrate [4].

The component insertion and assembly is carried out, for example as shown in FIG. 2. This can be accomplished using a robot or other suitable positioning system. The passive assembly using the replicated microstructure results in a fast and highly accurate positioning of the component. The permanent fixing and/or encapsulation of the component is accomplished by applying a drop of uv- or thermally curable adhesive or epoxy (see example in FIG. 2).

As an alternative to the replication approach, the original structure can be fabricated directly on the device and used as the ultimate alignment microstructure. This can be of interest if only very few microsystems are required.

The original microstructure with the rounded edges and taper can also be fabricated by other techniques and applied in the same way using replication technology.

An important application of this invention is the pigtailing of fibres to VCSEL devices, as illustrated in FIG. 2. This can be carried out at the individualised, mounted device level or at the wafer level. The latter approach is of interest for the high volume, low-cost production of VCSEL and other devices with fibre pigtails. Coupling efficiencies in excess of 70% have been demonstrated experimentally using this approach with multimode VCSEL arrays and fibres.

FIG. 1a shows in cross-sectional form a microstructure 1 having apertures 2 in which optical fibres 3 are located. The apertures 2 have rounded edges 4 to enable the optical fibres to be more easily located in the apertures.

FIG. 1b shows in cross-sectional form a second microstructure 10 having apertures 11 in which optical fibres 12 are located. The apertures 11 have rounded edges 13 to assist in locating the ends of the optical fibre 12 in the apertures 11.

FIG. 1c shows an arrangement for aligning microsystem components and sub-systems. Specifically, it shows in cross-section a third microstructure in which a micro-optical element (or lenslet) 30 with alignment features 31 is accurately positioned on a substrate device 32 with matching replicated alignment microstructures 33.

FIG. 2 shows a microstructure 20 mounted on a VCSEL chip 21 so that optical fibres 22 are located by apertures 23 over optical devices on the VCSEL chip 21. The chip 21 is mounted on a substrate 24 and wire bonded 25 to connection pads 26. The chip 21 and microstructure 20 are encapsulated in a suitable material 27 to protect them from mechanical damage and/or hostile environments.

The following references are hereby incorporated in this application by reference.

1. U.S. Pat. No. 4,949,350: Surface emitting semiconductor laser

2. U.S. Pat. No. 5,774,614: Optoelectronic coupling and method of making same

3. M. T. Gale, Replication, Ch. 6 in Micro-Optics: Elements, systems and applications, H. P. Herzig, Ed., Taylor and Francis, London (1997), ISBN 0 7484 04813 HB.

4. U.S. Pat. No. 5,833,903: Injection molding encapsulation for an electronic device directly onto a substrate.

1. A microstructure formed on or for application to a surface of a substrate in which one or more optoelectronic devices are formed, the microstructure having one or more apertures aligned with the optoelectronic devices and extending inwardly from an external surface thereof, the outer edges of the apertures being rounded in a plane normal to the external surface.

2. A microstructure as claimed in claim 1 wherein the apertures include portion tapering inwardly in a direction normal to the surface.

3. A method of fabricating a microstructure as claimed in claim 1 comprising the steps of:
depositing a high viscosity positive photo resist film on a substrate;
drying the resist film on a thermal hotplate running a ramped temperature profile;
exposing the film by contact mask lithography;
developing the film using a positive photo resist developer; and
subjecting the substrate to an extended and optimised hard bake in a convection oven to produce a controlled rounding of the edges of the microstructure.

4. A method as claimed in claim 3 in which the film is deposited by spin coating.

5. A method as claimed in claim 3 in which the thickness of the film is between 10 and 100 micrometers.

6. A method as claimed in claim 4 in which the microstructure includes insertion holes, for inserting and positioning optical fibres or other components, having rounded edges.

7. A method as claimed in claim 6 in which the insertion holes taper inwardly from the outer surface of the microstructure.

8. A method as claimed in claim 3 in which the substrate is a silicon wafer, an optoelectronic device wafer, or a glass substrate.

9. A method as claimed in claim 3 comprising the further step of fabricating a replication mould from the microstructure.

10. A method as claimed in claim 9 in which the replication mould is fabricated as an elastomeric casting mould in a heteropolysiloxane material.

11. A method as claimed in claim 11 in which the replication mould is used to fabricate further microstructures.

12. A method as claimed in claim 11 in which the microstructure is replicated into a UV-curable polymer.

13. A method as claimed in claim 12 in which the microstructure is replicated into a sol-gel.

14. A method as claimed in claim 12 in which the replication is carried out using a high precision robot to dispense the polymer or sol-gel and to position the replication mould.

15. A method as claimed in claim 12 for use in wafer scale replication in which a modified mask aligner is used to position replication moulds on the substrate.

16. A microstructure fabricated by a method as claimed in claim 3.

17. A method of component insertion comprising the steps of:
producing a microstructure as claimed in claim 1; and
loading the component by inserting it into one or more of said apertures.

18. A method as claimed in claim 17 in which the component is located with respect to the apertures of the microstructure by means of a robot.

19. A method of assembling a component comprising the steps of:
locating a microstructure as claimed in claim 1 on a substrate;
inserting the component into one or more of said apertures; and
fixing the component with respect to the microstructure.

20. A method as claimed in claim 19 comprising the further step of encapsulating the component.

21. A method as claimed in claim 19 in which the fixing and/or encapsulating step comprises applying a UV or thermally curable adhesive or resin and curing the adhesive or resin.

22. A method as claimed in claim 19 in which optoelectronic device(s) is/are formed on the substrate, the microstructures are formed over the optoelectronic devices, and optical fibres are located with respect to the optoelectronic devices by the microstructures.

23. A method as claimed in claim 22 in which the optoelectronic devices are lasers.

24. A method as claimed in claim 23 in which the lasers are vertical cavity surface emitting lasers.

25. A method as claimed in claim 23 in which the optoelectronic devices are detectors.

26. A component assembly produced by a method as claimed in claim 19.
